(19) United States
(12) Patent Application Publication
(10) Pub. No.: US 2011/0115693 A1
(43) Pub. Date: May 19, 2011

(54) Display Device

(76) Inventor: Eun-Ah Kim, Yongin-city (KR)

(21) Appl. No.: 12/946,744

(22) Filed: Nov. 15, 2010

(30) Foreign Application Priority Data
Nov. 17, 2009 (KR) 10-2009-0111106

(51) Int. Cl. G09G 3/30

(52) U.S. Cl. 345/76

(57) ABSTRACT

A display device includes a first display panel and a second display panel. The first display panel displays a first image in a first direction. The second display panel is on the first display panel and shares a common substrate with the first display panel. The second display panel displays a second image in the first direction. The second image at least partially overlaps the first image.

### CROSS-REFERENCE TO RELATED APPLICATIONS

This application claims priority to and the benefit of Korean Patent Application No. 10-2009-0111106, filed in the Korean Intellectual Property Office on Nov. 17, 2009, the entire content of which is incorporated herein by reference.

### BACKGROUND

1. Field

Aspects of embodiments according to the present invention relate generally to a display device.

2. Description of the Related Art

A display device is a device that displays an image. Currently, an organic light emitting diode (OLED) display is in the spotlight.

Unlike a liquid crystal display (LCD), the OLED display has self-luminous characteristics and does not require a separate light source. Thus, the OLED display can have reduced thickness and weight when compared to the LCD. Further, the OLED display has high quality characteristics such as low power consumption, high luminance, and a high reaction speed, and thus has been in the spotlight as a next generation display device of a portable electronic device.

Because the OLED display displays an image in a two-dimensional plane, the OLED display is limited in its ability to display a three-dimensional image. Further, since in the OLED display, an OLED including an emission layer is located in a sealed space between opposing substrates, after the OLED display is manufactured, a failure in a pixel normally might mean that an entire OLED display needs to be disposed of. In addition, in the OLED display, because an organic emission layer is made of an organic material, the life span of the emission layer is not long, and thus it is difficult to display an image of a fixed pattern shape for a long time.

The above information disclosed in this Background section is only for enhancement of understanding of the background of the described technology and therefore it may contain information that does not form the prior art that is already known in this country to a person of ordinary skill in the art.

### SUMMARY

Aspects of embodiments according to the present invention are directed towards a display device capable of displaying a three-dimensional image. Embodiments further provide a display device capable of suppressing disposal of an organic light emitting display panel in which a pixel failure occurs. Embodiments still further provide a display device including an organic light emitting display panel that displays an image of a fixed pattern shape for a long time.

According to an exemplary embodiment of the present invention, a display device is provided. The display device includes a first display panel and a second display panel on the first display panel. The first display panel includes a common substrate and is configured to display a first image in a first direction. The second display panel includes the common substrate and is configured to display a second image in the first direction. The second image overlaps with at least a part of the first image.

The second display panel may be a light transmitting structure.

The first display panel may further include a first substrate opposing the common substrate. The second display panel may further include a third substrate opposing the first substrate with the common substrate therebetween.

The first display panel may further include a first organic light emitting diode (OLED) between the first substrate and the common substrate. The first OLED includes a first electrode, a first organic emission layer, and a second electrode sequentially stacked on the first substrate or the common substrate.

The second display panel may further include a second OLED between the common substrate and the third substrate. The second OLED includes a third electrode, a second organic emission layer, and a fourth electrode sequentially stacked on the common substrate or the third substrate.

The third electrode and the fourth electrode may be a light transmitting conducting material.

The third electrode, the second organic emission layer, and the fourth electrode may be sequentially stacked on the common substrate.

The first electrode, the first organic emission layer, and the second electrode may be sequentially stacked on the common substrate.

The first display panel may further include a first plurality of pixels that includes the first OLED. The second display panel may further include a second plurality of pixels that includes the second OLED.

It may be that none of the first plurality of pixels overlaps any of the second plurality of pixels.

The third electrode may be a light reflecting conducting material.

The first electrode may be a light reflecting conducting material.

The second plurality of pixels may be configured to be light transmitting.

The display device may further include a third display panel on the second display panel. The third display panel is configured to display a third image in the first direction. The third image at least partially overlaps at least one of the first image or the second image. The second display panel and the third display panel include at least one identical substrate.

According to another exemplary embodiment of the present invention, another display device is provided. The display device includes a first display panel, a second display panel on the first display panel, and a third display panel on the second display panel. The first display panel includes a first substrate and a second substrate opposing the first substrate. The first display panel is configured to display a first image in a first direction. The second display panel includes the second substrate and a third substrate opposing the first substrate with the second substrate therebetween. The second display panel is configured to display a second image in the first direction. The second image overlaps with at least a part of the first image. The third display panel includes the third substrate and a fourth substrate opposing the first and second substrates with the third substrate therebetween. The third display panel is configured to display a third image in the first direction. The third image overlaps with at least a part of at least one of the first image or the second image.

The first display panel may further include a first organic light emitting diode (OLED) between the first substrate and the second substrate. The first OLED includes a first electrode, a first organic emission layer, and a second electrode sequentially stacked on the first substrate or the second substrate. The second display panel may further include a second OLED between the second substrate and the third substrate. The second OLED includes a third electrode, a second organic emission layer, and a fourth electrode sequentially stacked on the second substrate or the third substrate. The third display panel may further include a third OLED between the third substrate and the fourth substrate. The third OLED includes a fifth electrode, a third organic emission layer, and a sixth electrode sequentially stacked on the third substrate or the fourth substrate.

The fifth electrode and the sixth electrode may be a light transmitting conducting material.

The third electrode and the fourth electrode may be a light transmitting conducting material.

The third display panel may be configured to be light transmitting.

The second display panel may be configured to be light transmitting.

According to the exemplary embodiments, as the display device includes the first display panel and the second display panel, the display device can display a three-dimensional image. In addition, disposal of an organic light emitting display panel in which a pixel failure occurs can be suppressed. Also, the display device can provide an organic light emitting display panel that displays an image of a fixed pattern shape for a long time.

### BRIEF DESCRIPTION OF THE DRAWINGS

The accompanying drawings, together with the specification, illustrate exemplary embodiments of the present invention and, together with the description, serve to explain the principles of aspects of the present invention.

FIG. 1 is a cross-sectional view illustrating a display device according to a first exemplary embodiment.

FIG. 2 is a layout view illustrating a structure of a pixel of a display device according to an exemplary embodiment.

FIG. 3 is a cross-sectional view of the pixel taken along the line of FIG. 2.

FIG. 4 is a cross-sectional view illustrating a display device according to a second exemplary embodiment.

FIG. 5 is a cross-sectional view illustrating a display device according to a third exemplary embodiment.

### DETAILED DESCRIPTION

Exemplary embodiments of the present invention will be described more fully hereinafter with reference to the accompanying drawings, in which exemplary embodiments are shown. As those skilled in the art would realize, the described embodiments may be modified in various different ways, all without departing from the spirit or scope of the present invention.

Further, like reference numerals designate like elements in several exemplary embodiments and are representatively described in the first exemplary embodiment, and different elements from the first exemplary embodiment will be described in other exemplary embodiments.

The drawings and description are to be regarded as illustrative in nature and not restrictive. Like reference numerals designate like elements throughout the specification. Further, the size and thickness of each of elements displayed in the drawings are illustrated for better understanding and ease of description, and the exemplary embodiment is not limited by the described size and thickness.

In the drawings, the thickness of layers, films, panels, regions, etc., are exaggerated for clarity. In the drawings, for better understanding and ease of description, thicknesses of some layers and areas are excessively displayed. When it is said that any part, such as a layer, film, region, or plate, is positioned on another part, it means the part is directly on the other part or above the other part with at least one intermediate part therebetween. If any part is said to be positioned directly on another part, it means that there is no intermediate part between the two parts.

Further, in the following description, in an exemplary embodiment, an organic light emitting display panel including an organic emission layer is described as a display panel, but the display panel is not limited thereto. That is, the display panel according to the exemplary embodiment may be a display panel such as a liquid crystal display panel, a plasma display panel (PDP), or a field emission display panel.

Therefore, in the accompanying drawings, an active matrix (AM) type of organic light emitting display panel of a two-transistor one-capacitor (2Tr-1Cap) structure having two thin film transistors (TFT) and one capacitor is described in one pixel, but the exemplary embodiment is not limited thereto. Therefore, in the organic light emitting display panel, the quantity of thin film transistors, the quantity of capacitors, and the quantity of wires are not limited. A pixel may represent a minimum unit that displays an image, and the organic light emitting display panel displays an image through a plurality of pixels.

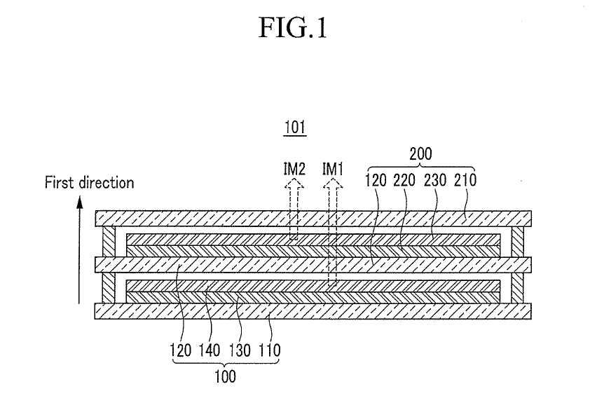

Exemplary embodiments will be described hereinafter with reference to FIGS. 1 to 5.

FIG. 1 is a cross-sectional view illustrating a display device according to a first exemplary embodiment. As shown in FIG. 1, a display device 101 includes a first display panel 100 and a second display panel 200.

The first display panel 100 displays a first image IM1 in a first direction, which is a direction towards one side (for example, the top), and the first image IM1 transmits through the second display panel 200. The first display panel 100 includes a first substrate 110, a second substrate 120, a first driving circuit 130, and a first OLED 140.

The first substrate 110 is an insulation substrate that is, for example, formed with glass, quartz, ceramic, or plastic. However, the first substrate 110 is not limited thereto, and it may be a metal substrate that is formed with stainless steel, etc.

The second substrate 120 opposes the first substrate 110 and covers the first OLED 140 and the first driving circuit 130. The second substrate 120 is made of a transparent material such as glass, quartz, or plastic.

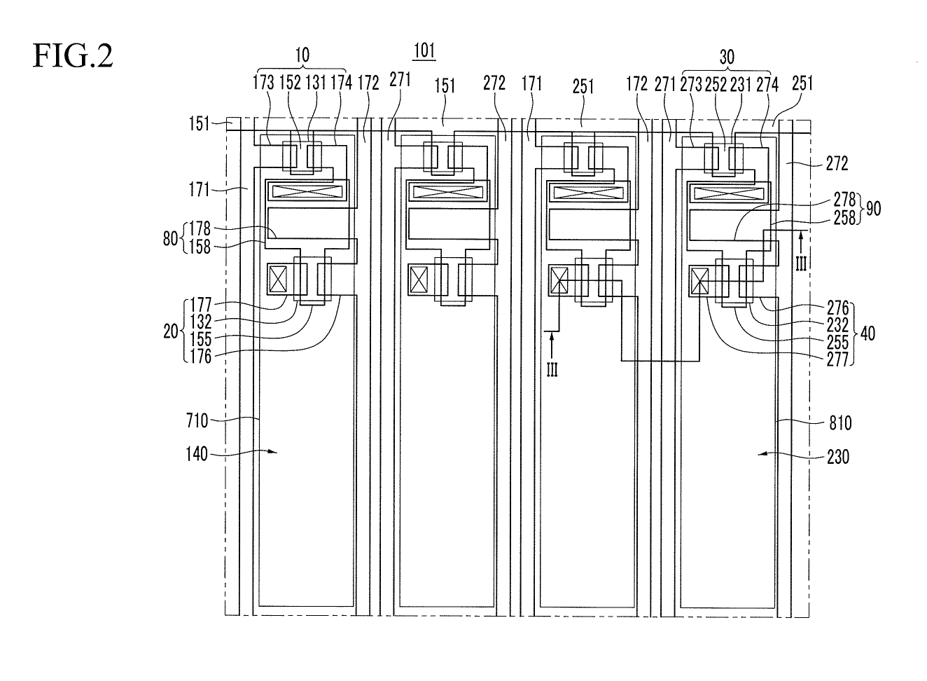

The first driving circuit 130 and the first OLED 140 are located (e.g., formed) on the first substrate 110 and positioned between the first substrate 110 and the second substrate 120. The first driving circuit 130 includes first and second (or first switching and first driving) thin film transistors 10 and 20 (shown in FIG. 2), and drives the first OLED 140. The first OLED 140 emits light according to a driving signal received from the first driving circuit 130, and displays the first image IM1 in the first direction.

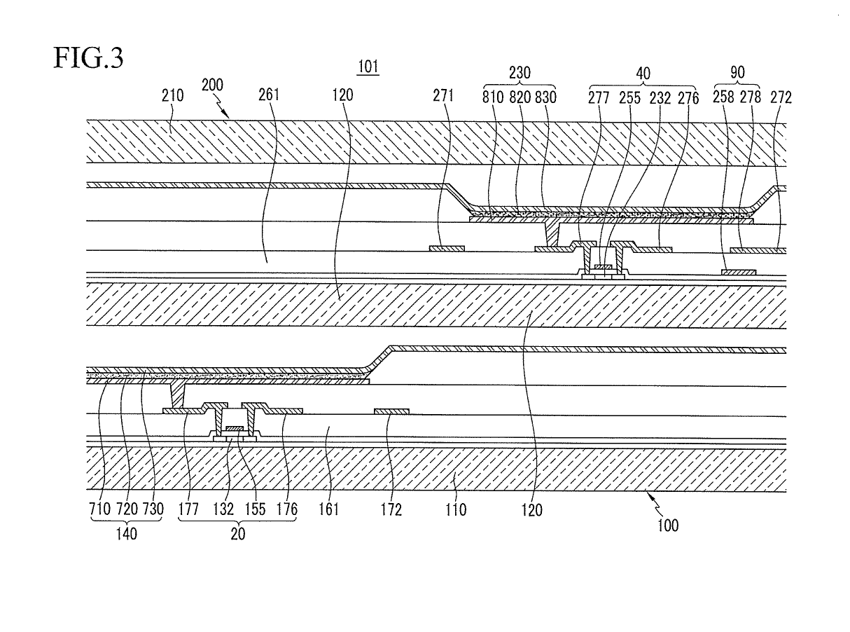

A detailed structure of the first OLED 140 and the first driving circuit 130 is shown in FIGS. 2 and 3, but the described exemplary embodiment is not limited to the structure shown in FIGS. 2 and 3. The first OLED 140 and the first driving circuit 130 can be formed in various structures within a range that can be easily modified by a person of ordinary skill in the art.

The second display panel 200 is positioned on the first display panel 100. The second display panel 200 displays a second image IM2 in the first direction. The second image IM2 displayed by the second display panel 200 and the first image IM1 displayed by the first display panel 100 are partially or entirely overlapped to form an image displayed by the display device 101. That is, when the first image IM1 and the second image IM2, which are two-dimensional images, are overlapped with a phase difference, an image of the display device 101 formed by the first image IM1 and the second image IM2 can be viewed as a three-dimensional image.

One image of the first image IM1 and the second image IM2 can be displayed as a more complicated image than the other image. When a single-panel OLED display device displays a complicated image, the life span of the device may be shortened, but when the first image IM1 and the second image IM2 selectively (for example, alternately) display a complicated image (that is, using multiple OLED panels), the life span of the display device 101 is improved.

Further, one image of the first image IM1 and the second image IM2 can be displayed as an image of a fixed pattern shape, compared with the other image. When a single panel OLED display device displays an image of a fixed pattern shape, the life-span of the device may be shortened, but when the first image IM1 and the second image IM2 selectively display a fixed pattern shape (that is, using multiple OLED panels), the life-span of the display device 101 is improved.

The second display panel 200 includes the second substrate 120, a third substrate 210, a second driving circuit 220, and a second OLED 230. Here, the first display panel 100 and the second display panel 200 share the second substrate 120. In this way, the display device 101 according to the first exemplary embodiment can have a reduced manufacturing cost, compared with a display device including a plurality of panels using different substrates.

The third substrate 210 opposes the second substrate 120 and covers the second OLED 230 and the second driving circuit 220. The third substrate 210 is made of a transparent material such as glass, quartz, or plastic.

The second driving circuit 220 and the second OLED 230 are located (e.g., formed) on the second substrate 120 and positioned between the second substrate 120 and the third substrate 210. The second driving circuit 220 includes third and fourth (or second switching and second driving) thin film transistors 30 and 40 (shown in FIG. 2), and drives the second OLED 230. The second OLED 230 emits light according to a driving signal received from the second driving circuit 220, and displays the second image IM2 in the first direction. The second OLED 230 and the second driving circuit 220 may be formed as light transmitting structures. That is, the second display panel 200 may be formed as a light transmitting structure so that the first image IM1 displayed in the first display panel 100 may transmit therethrough.

A detailed structure of the second OLED 230 and the second driving circuit 220 is shown in FIGS. 2 and 3, but the present exemplary embodiment is not limited to the structure shown in FIGS. 2 and 3. The second OLED 230 and the second driving circuit 220 can be formed in various structures within a range that can be easily modified by a person of ordinary skill in the art.

An inner structure of the display device 101 will be described in detail hereinafter with reference to FIGS. 2 and 3.

FIG. 2 is a layout view illustrating a structure of a pixel of a display device according to the first exemplary embodiment. FIG. 3 is a cross-sectional view of the pixel taken along the line III-III of FIG. 2. It should be noted that FIG. 2 shows four pixels side-by-side, alternating between pixels on the first display panel 100 and the second display panel 200.

As shown in FIGS. 2 and 3, the first display panel 100 includes a first switching thin film transistor 10, a first driving thin film transistor 20, a first capacitor 80, and a first OLED 140 formed, respectively, in each pixel. Here, a configuration including the first switching thin film transistor 10, the first driving thin film transistor 20, and the first capacitor 80 is referred to as the first driving circuit 130. The first driving circuit 130 further includes a first gate line 151 extending in one direction on the first substrate 110, and a first data line 171 and a first common power line 172 that are insulated from and cross the first gate line 151.

Here, a pixel of the first display panel 100 is defined by the first gate line 151, the first data line 171, and the first common power line 172 as a boundary thereof, but a pixel is not limited thereto. Further, neighboring pixels of the first display panel 100 according to the first exemplary embodiment are formed with a gap (for example, a predetermined gap) between neighboring pixels of the second display panel 200, but the neighboring pixels of the first display panel 100 are not limited thereto and can be formed to overlap (e.g., partially or completely overlap) the neighboring pixels of the second display panel 200.

The first OLED 140 includes a first electrode 710, a first organic emission layer 720 on the first electrode 710, and a second electrode 730 on the first organic emission layer 720. Here, the first electrode 710 is a positive (+) electrode, which is a hole injection electrode, and the second electrode 730 is a negative (−) electrode, which is an electron injection electrode. However, the first exemplary embodiment is not limited thereto, and the first electrode 710 may be a negative electrode and the second electrode 730 may be a positive electrode according to a driving method of the first display panel 100. When holes and electrons are injected into the first organic emission layer 720 from the first electrode 710 and the second electrode 730, respectively, and when excitons formed by combining holes and electrons injected into the first organic emission layer 720 drop from an excited state to a ground state, the first organic emission layer 720 emits light.

Further, in the first display panel 100 according to the first exemplary embodiment, the first OLED 140 emits light in a direction towards the second substrate 120. That is, the first OLED 140 is a front surface light emitting type (e.g., a top emission type). Here, in order for the first OLED 140 to emit light in the first direction, which is a direction towards the second substrate 120, the first electrode 710 is made of a light reflecting conducting material and the second electrode 730 is made of a light transmitting conducting material.

The first capacitor 80 includes a pair of first capacitor plates 158 and 178 with a first interlayer insulating layer 161 interposed therebetween. Here, the first interlayer insulating layer 161 is a dielectric material, and the capacitance of the first capacitor 80 is determined by charges stored in the first capacitor 80 and a voltage between the first capacitor plates 158 and 178.

The first switching thin film transistor 10 includes a first switching semiconductor layer 131, a first switching gate electrode 152, a first switching source electrode 173, and a first switching drain electrode 174. The first driving thin film transistor 20 includes a first driving semiconductor layer 132, a first driving gate electrode 155, a first driving source electrode 176, and a first driving drain electrode 177.

The first switching thin film transistor 10 is used as a switch for selecting a pixel to emit light. The first switching gate electrode 152 is connected to the first gate line 151. The first switching source electrode 173 is connected to the first data line 171. The first switching drain electrode 174 is separated from the first switching source electrode 173 and is connected to the first capacitor plate 158.

The first driving thin film transistor 20 applies a driving power for allowing light emission of the first organic emission layer 720 of the first OLED 140 within the selected pixel to the first electrode 710. The first driving gate electrode 155 is connected to the first capacitor plate 158 that is connected to the first switching drain electrode 174. The first driving source electrode 176 and the other first capacitor plate 178 are each connected to the first common power line 172. The first driving drain electrode 177 is connected to the first electrode 710 of the first OLED 140 through a contact hole.

By such a structure, the first switching thin film transistor 10 operates by a gate voltage applied to the first gate line 151 and performs a function of transferring a data voltage applied to the first data line 171 to the first driving thin film transistor 20. A voltage corresponding to a difference between a common voltage applied from the first common power line 172 to the first driving thin film transistor 20 and a data voltage transferred from the first switching thin film transistor 10 is stored in the first capacitor 80, and a current corresponding to a voltage stored in the first capacitor 80 flows to the first OLED 140 through the first driving thin film transistor 20 and thus the first OLED 140 emits light. The second display panel 200 including the second substrate 120 is disposed on the first OLED 140 to protect the first OLED 140.

The second display panel 200 includes a second switching thin film transistor 30, a second driving thin film transistor 40, a second capacitor 90, and a second OLED 230 formed in a light transmitting structure in each pixel. Here, a configuration including the second switching thin film transistor 30, the second driving thin film transistor 40, and the second capacitor 90 is referred to as the second driving circuit 220. The second driving circuit 220 further includes a second gate line 251 extending in one direction on the second substrate 120 and made of a light transmitting conducting material, and a second data line 271 and a second common power line 272 that are insulated from and cross the second gate line 251.

Here, a pixel of the second display panel 200 is defined by the second gate line 251, the second data line 271, and the second common power line 272 as a boundary, but a pixel is not limited thereto. Further, neighboring pixels of the second display panel 200 according to the first exemplary embodiment are formed with a gap (for example, a predetermined gap) between neighboring pixels of the first display panel 100, but the neighboring pixels of the second display panel 200 are not limited thereto and can be formed to overlap the neighboring pixels of the first display panel 100.

The second OLED 230 includes a third electrode 810 made of a light transmitting conducting material, a second organic emission layer 820 on the third electrode 810, and a fourth electrode 830 on the second organic emission layer 820 and made of a light transmitting conducting material. Here, the third electrode 810 is a positive (+) electrode, which is a hole injection electrode, and the fourth electrode 830 is a negative (−) electrode, which is an electron injection electrode. However, the first exemplary embodiment is not limited thereto, and the third electrode 810 may be a negative electrode and the fourth electrode 830 may be a positive electrode according to a driving method of the second display panel 200. When holes and electrons are injected into the second organic emission layer 820 from the third electrode 810 and the fourth electrode 830, respectively, and when excitons formed by combining holes and electrons injected into the second organic emission layer 820 drop from an excited state to a ground state, the second organic emission layer 820 emits light.

Further, in the second display panel 200 according to the first exemplary embodiment, because the third electrode 810 and the fourth electrode 830 are made of a light transmitting conducting material, the second OLED 230 is a two-surface light emitting type (e.g., a dual emission type) that emits light in directions towards the second substrate 120 and the third substrate 210.

In another exemplary embodiment, when the third electrode 810 is made of a light reflecting conducting material and the fourth electrode is made of a light transmitting conducting material, the second OLED 230 of the second display panel 200 is formed as a front surface light emitting type (e.g., a top emission type). In this case, each pixel of the first display panel 100 should be positioned between neighboring pixels of the second display panel 200 so that the first image IM1 displayed in the first display panel 100 may transmit through the second display panel 200, and neighboring pixels of the second display panel 200 are formed in a light transmitting structure.

The second capacitor 90 includes a pair of second capacitor plates 258 and 278 with a second interlayer insulating layer 261 interposed therebetween. Here, the second interlayer insulating layer 261 is a dielectric material, and the capacitance of the second capacitor 90 is determined by charges stored in the second capacitor 90 and a voltage between the second capacitor plates 258 and 278.

The second switching thin film transistor 30 includes a second switching semiconductor layer 231, a second switching gate electrode 252, a second switching source electrode 273, and a second switching drain electrode 274. The second driving thin film transistor 40 includes a second driving semiconductor layer 232, a second driving gate electrode 255, a second driving source electrode 276, and a second driving drain electrode 277.

The second switching thin film transistor 30 is used as a switch for selecting a pixel to emit light. The second switching gate electrode 252 is connected to the second gate line 251. The second switching source electrode 273 is connected to the second data line 271. The second switching drain electrode 274 is separated from the second switching source electrode 273 and is connected to one of the second capacitor plates 258.

The second driving thin film transistor 40 applies a driving power for allowing light emission of the second organic emission layer 820 of the second OLED 230 within the selected pixel to the third electrode 810. The second driving gate electrode 255 is connected to the second capacitor plate 258 that is connected to the second switching drain electrode 274. The second driving source electrode 276 and the other second capacitor plate 278 are each connected to the second common power line 272. The second driving drain electrode 277 is connected to the third electrode 810 of the second OLED 230 through a contact hole.

By such a structure, the second switching thin film transistor 30 performs a function of transferring a data voltage applied to the second data line 271 to the second driving thin film transistor 40 when a gate voltage is applied to the second gate line 251. A voltage corresponding to a difference between a common voltage applied from the second common power line 272 to the second driving thin film transistor 40 and a data voltage transferred from the second switching thin film transistor 30 is stored in the second capacitor 90, and a current corresponding to a voltage stored in the second capacitor 90 flows to the second OLED 230 through the second driving thin film transistor 40 and thus the second OLED 230 emits light. The third substrate 210 that opposes the second substrate 120 is disposed on the second OLED 230 to protect the second OLED 230.

For better understanding and ease of description, the first display panel 100 and the second display panel 200 according to the exemplary embodiment of FIGS. 1-3 are each formed as an organic light emitting display panel including an OLED, but the exemplary embodiment is not limited thereto and each of the first display panel 100 and the second display panel 200 may be one of a liquid crystal display panel, a PDP, a display panel in which a plurality of light emitting diodes (LED) are disposed, or a field emission display panel. In addition, a display device according to the exemplary embodiment can be driven with driving methods appropriate for a combination of display panels that are selected by each of the first display panel 100 and the second display panel 200.

As described above, the display device 101 includes the first display panel 100 that displays the first image IM1 in the first direction, which is a direction towards one side, and the second display panel 200 that displays the second image IM2 that is partially or entirely overlapped with the first image IM1. The first image IM1 and the second image IM2, which are two-dimensional images, are overlapped with a phase difference to form an image that can be three-dimensionally viewed. That is, the display device 101 according to the first exemplary embodiment displays an image that can be viewed as a three-dimensional image.

Further, in the display device 101 according to the first exemplary embodiment, because a pixel of the first display panel 100 and a pixel of the second display panel 200 overlap each other or are adjacent to each other, even if a failure occurs in one or more pixels of the first display panel 100 or one or more pixels of the second display panel 200, a pixel of one display panel in which the failure occurs can have its image data displayed by a nearby pixel of another display panel.

In more detail, if a failure occurs in a pixel of the second display panel 200, a pixel of the first display panel 100, adjacent to the pixel of the second display panel 200 in which the failure occurs, can replace the pixel of the second display panel 200 in which the failure occurs by displaying the image data of the pixel of the second display panel 200. That is, in the display device 101 according to the first exemplary embodiment, the first display panel 100 and the second display panel 200 are formed as organic light emitting display panels that otherwise might be disposed when a failure pixel occurs, but because a pixel in which a failure occurs can be bypassed using neighboring pixels, disposal of the display device 101 in which a failure pixel occurs can be suppressed.

Further, in the display device 101 according to the first exemplary embodiment, because one image of the first image IM1 or the second image IM2 can be selectively (for example, alternately) displayed as a more complicated image or an image of a fixed pattern shape, compared with the other image, the life-span of the first organic emission layer 720 and the second organic emission layer 820 is improved and thus the life-span of the display device 101 is improved.

In another exemplary embodiment, when the first display panel 100 includes an LED that displays only an image of a fixed pattern shape and the second display panel 200 includes an OLED that displays only a complicated image are provided, the life-span of the display device 101 can be improved.

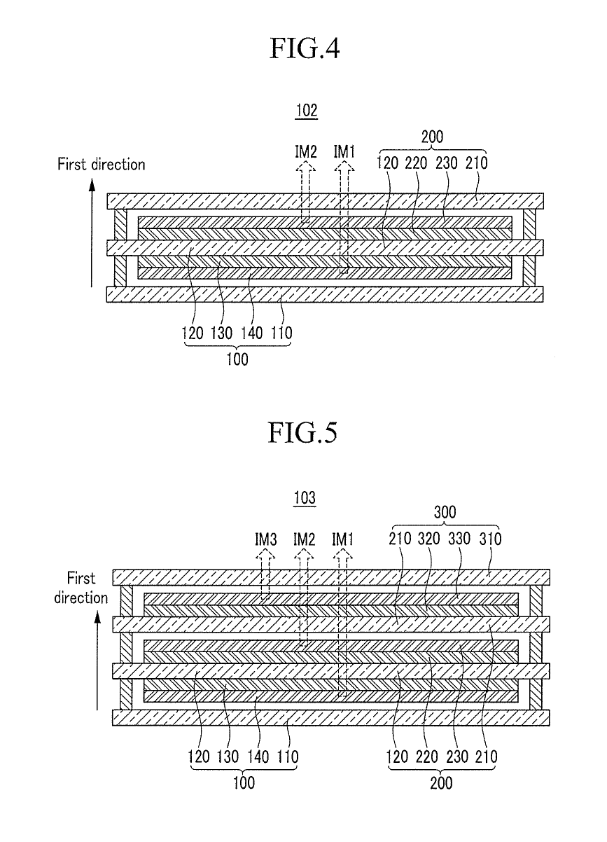

A display device 102 according to a second exemplary embodiment will be described hereinafter with reference to FIG. 4. FIG. 4 is a cross-sectional view illustrating the display device 102.

The display device 102 includes a first display panel 100 and a second display panel 200. The first display panel 100 displays a first image IM1 in a first direction, which is a direction towards one side (for example, the top of the display device 102), and the first image IM1 transmits through the second display panel 200. The first display panel 100 includes a first substrate 110, a second substrate 120, a first driving circuit 130, and a first OLED 140.

The first driving circuit 130 drives the first OLED 140 and is formed on the second substrate 120. The first OLED 140 emits light according to a driving signal received from the first driving circuit 130 and displays the first image IM1 in the first direction.

The second display panel 200 displays the second image IM2 in the first direction. The second display panel 200 includes the second substrate 120, a third substrate 210, a second driving circuit 220, and a second OLED 230.

The second driving circuit 220 drives the second OLED 230 and is formed on the second substrate 120. The second OLED 230 emits light according to a driving signal received from the second driving circuit 220 and displays the second image IM2 in the first direction.

As described above, in the display device 102 according to the embodiment of FIG. 4, because the first driving circuit 130 and the first OLED 140 of the first display panel 100 and the second driving circuit 220 and the second OLED 230 of the second display panel 200 are formed on the second substrate 120, by forming a plurality of first OLEDs 130 and second OLEDs 230 on one substrate, the manufacturing complexity can be reduced.

A display device 103 according to a third exemplary embodiment will be described hereinafter with reference to FIG. 5. FIG. 5 is a cross-sectional view illustrating the display device 103.

The display device 103 includes a first display panel 100, a second display panel 200, and a third display panel 300. The first display panel 100 displays a first image IM1 in a first direction, which is a direction towards one side (for example, the top of the display device 103), and the first image IM1 transmits through the second display panel 200. The first display panel 100 includes a first substrate 110, a second substrate 120, a first driving circuit 130, and a first OLED 140.

The first driving circuit 130 drives the first OLED 140 and is formed on the second substrate 120. The first OLED 140 emits light according to a driving signal received from the first driving circuit 130 and displays the first image IM1 in the first direction.

The second display panel 200 displays a second image IM2 in the first direction. The second display panel 200 includes the second substrate 120, a third substrate 210, a second driving circuit 220, and a second OLED 230.

The second driving circuit 220 drives the second OLED 230 and is formed on the second substrate 120. The second OLED 230 emits light according to a driving signal received from the second driving circuit 220 and displays the second image IM2 in the first direction.

The third display panel 300 is positioned on the second display panel 200 and displays a third image IM3 in the first direction. The third display panel 300 includes the third substrate 210, a fourth substrate 310, a third driving circuit 320, and a third OLED 330. The third driving circuit 320 and the third OLED 330 are positioned between the third substrate 210 and the fourth substrate 310, and the third OLED 330 emits light according to a driving signal received from the third driving circuit 320 and displays the third image IM3 in the first direction.

The third display panel 300 is formed in a light transmitting structure, and the first image IM1 of the first display panel 100 and the second image IM2 of the second display panel 200 transmit through the third display panel 300. As the first image IM1 and the second image IM2 transmit through the third display panel 300, the third image IM3 of the third display panel 300 at least partially overlaps with at least one of the first image IM1 and the second image IM2 to form an image that is displayed by the display device 103.

As described above, as the first image IM1, the second image IM2, and the third image IM3, which are two-dimensional images, are displayed in the same first direction with respective phase differences, the display device 103 according to the third exemplary embodiment displays an image that can be viewed as a more complicated three-dimensional image, compared with the display device 101 according to the first exemplary embodiment or the display device 102 according to the second exemplary embodiment.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A display device comprising:
a first display panel comprising a common substrate and configured to display a first image in a first direction; and
a second display panel on the first display panel, the second display panel comprising the common substrate and configured to display a second image in the first direction, the second image overlapping with at least a part of the first image.

2. The display device of claim 1, wherein the second display panel is a light transmitting structure.

3. The display device of claim 1, wherein:
the first display panel further comprises a first substrate opposing the common substrate, and
the second display panel further comprises a third substrate opposing the first substrate with the common substrate therebetween.

4. The display device of claim 3, wherein the first display panel further comprises a first organic light emitting diode (OLED) between the first substrate and the common substrate, the first OLED comprising a first electrode, a first organic emission layer, and a second electrode sequentially stacked on the first substrate or the common substrate.

5. The display device of claim 4, wherein the second display panel further comprises a second OLED between the common substrate and the third substrate, the second OLED comprising a third electrode, a second organic emission layer, and a fourth electrode sequentially stacked on the common substrate or the third substrate.

6. The display device of claim 5, wherein the third electrode and the fourth electrode comprise a light transmitting conducting material.

7. The display device of claim 5, wherein the third electrode, the second organic emission layer, and the fourth electrode are sequentially stacked on the common substrate.

8. The display device of claim 7, wherein the first electrode, the first organic emission layer, and the second electrode are sequentially stacked on the common substrate.

9. The display device of claim 5, wherein:
the first display panel further comprises a first plurality of pixels comprising the first OLED, and
the second display panel further comprises a second plurality of pixels comprising the second OLED.

10. The display device of claim 9, wherein none of the first plurality of pixels overlaps any of the second plurality of pixels.

11. The display device of claim 10, wherein the third electrode comprises a light reflecting conducting material.

12. The display device of claim 9, wherein the first electrode comprises a light reflecting conducting material.

13. The display device of claim 9, wherein the second plurality of pixels are configured to be light transmitting.

14. The display device of claim 1, further comprising a third display panel on the second display panel, the third display panel configured to display a third image in the first direction, the third image at least partially overlapping at least one of the first image or the second image,
wherein the second display panel and the third display panel comprise at least one identical substrate.

15. A display device comprising:
a first display panel comprising a first substrate and a second substrate opposing the first substrate, the first display panel configured to display a first image in a first direction;
a second display panel on the first display panel, the second display panel comprising the second substrate and a third substrate opposing the first substrate with the second substrate therebetween, the second display panel configured to display a second image in the first direction, the second image overlapping with at least a part of the first image; and
a third display panel on the second display panel, the third display panel comprising the third substrate and a fourth substrate opposing the first and second substrates with the third substrate therebetween, the third display panel configured to display a third image in the first direction, the third image overlapping with at least a part of at least one of the first image or the second image.

16. The display device of claim 15, wherein:
the first display panel further comprises a first organic light emitting diode (OLED) between the first substrate and the second substrate, the first OLED comprising a first electrode, a first organic emission layer, and a second electrode sequentially stacked on the first substrate or the second substrate,
the second display panel further comprises a second OLED between the second substrate and the third substrate, the second OLED comprising a third electrode, a second organic emission layer, and a fourth electrode sequentially stacked on the second substrate or the third substrate, and
the third display panel further comprises a third OLED between the third substrate and the fourth substrate, the third OLED comprising a fifth electrode, a third organic emission layer, and a sixth electrode sequentially stacked on the third substrate or the fourth substrate.

17. The display device of claim 16, wherein the fifth electrode and the sixth electrode comprise light transmitting conducting material.

18. The display device of claim 17, wherein the third electrode and the fourth electrode comprise light transmitting conducting material.

19. The display device of claim 17, wherein the third display panel is configured to be light transmitting.

20. The display device of claim 19, wherein the second display panel is configured to be light transmitting.
